(19) United States
(12) Patent Application Publication
(10) Pub. No.: US 2010/0109685 A1
(43) Pub. Date: May 6, 2010

(54) WIRELESS MOISTURE MONITORING DEVICE AND METHOD

(75) Inventor: David L. Morton, Sandy, UT (US)

Correspondence Address: Workman Nydegger;1000 Eagle Gate Tower, 60 East South Temple, Salt Lake City, UT, 84111, US

(73) Assignee: FERTILE EARTH SYSTEMS, INC., Sandy, UT (US)

(21) Appl. No.: 12/611,053

(22) Filed: Nov. 2, 2009

Related U.S. Application Data
(63) Continuation-in-part of application No. 29/329,073, filed on Dec. 8, 2008, now Pat. No. D609588.
Application No. 29/329,073 is a continuation-in-part of application No. 12/491,121, filed on Jun. 24, 2009.
(60) Provisional application No. 61/110,368, filed on Oct. 31, 2008.
(60) Provisional application No. 61/120,789, filed on Dec. 8, 2008.
(60) Provisional application No. 61/110,368, filed on Oct. 31, 2008.
(60) Provisional application No. 61/120,789, filed on Dec. 8, 2008.

(51) Int. Cl. G01R 27/08

(52) U.S. Cl. 324/696

(57) ABSTRACT

A wireless moisture monitoring device that measures the dielectric constant of a material to provide an indication of the water or moisture content of a material. The wireless moisture monitoring device can monitor the moisture level of a material constantly, periodically, or the device can be configured to provide an instantaneous indication of the moisture content of the material (e.g., soil). The moisture monitoring device can be used in conjunction with a moisture monitoring system that can be used to control a watering system (e.g., an irrigation system). A method for providing an instantaneous indication of the moisture content of a material is also disclosed.

### CROSS-REFERENCE TO RELATED APPLICATIONS

This application is a continuation-in-part of U.S. Design patent application Ser. No. 29/329,073 filed 8 Dec. 2008 and entitled “SOIL MOISTURE MONITORING DEVICE,” the entirety of which is incorporated herein by reference. This application is also a continuation-in-part of U.S. patent application Ser. No. 12/491,121 filed 24 Jun. 2009 and entitled “MOISTURE MONITORING DEVICE AND METHOD,” which claims the benefit of and priority to U.S. Provisional Application Ser. No. 61/110,368 filed 31 Oct. 2008 and entitled “SOIL MOISTURE MONITORING DEVICE AND METHOD” and U.S. Provisional Application Ser. No. 61/120,789 filed 8 Dec. 2008 and entitled “WIRELESS MOISTURE MONITORING SYSTEM AND METHOD,” the entireties of which are incorporated herein by reference. This application claims the benefit of and priority to U.S. Provisional Application Ser. No. 61/110,368 filed 31 Oct. 2008 and entitled “SOIL MOISTURE MONITORING DEVICE AND METHOD,” the entirety of which is incorporated herein by reference. This application also claims the benefit of and priority to U.S. Provisional Application Ser. No. 61/120,789 filed 8 Dec. 2008 and entitled “WIRELESS MOISTURE MONITORING SYSTEM AND METHOD,” the entirety of which is incorporated herein by reference.

### BACKGROUND OF THE INVENTION

1. Technical Field

The present invention relates generally to moisture sensing. More particularly, embodiments of the present invention relate to wireless moisture monitoring devices and methods which can monitor and/or control the watering needs of a plant, shrub, tree, grass, or the like.

2. The Relevant Technology

The ability to sense and measure moisture in a material or medium can provide significant benefits. Measuring the water content of a medium can be used, for example, to control sprinkling systems or to implement water conservation techniques. Several methods and devices for measuring water content or moisture of water permeable mediums or materials such as soil have traditionally been used.

One technique is to measure the dielectric constant of the medium under test. The dielectric constant of water is quite high at about 80. Materials or mediums such as soil, however, typically only have a dielectric constant of about 4. Changes in the water content of a particular medium will cause a change in the dielectric constant of the medium.

Unfortunately, the expense, power consumption, and sophisticated nature of conventional devices used in measuring moisture content of materials has been problematic. These traditional devices are often not suitable for in-home use by the average consumer to monitor the moisture content of a typical indoor potted plant's soil. At the same time these devices are often unsuitable for large scale implementations because of at least the cost and power consumption.

### BRIEF SUMMARY OF THE INVENTION

Embodiments of the present invention are directed to a wireless moisture monitoring device that can be used measure the moisture content of a material (e.g., soil) or other media. Embodiments of the present invention also include a wireless moisture monitoring system that can be used for wirelessly monitoring and controlling an irrigation system based upon moisture or water content of a material. In some instances, the material contains or supports plants, shrubs, trees, grass, or the like. A method for wirelessly providing an instantaneous or current indication of the moisture content of a material is also presented.

In one embodiment, a wireless device for measuring water content is disclosed. A wireless moisture monitoring device may generally be configured as a device having a probe and moisture sensing circuitry adapted for detecting water content when the probe is at least partially submerged in a material. The moisture sensing circuitry can be configured to produce a first signal that varies in magnitude with the water content of the material or that is indicative of the water or moisture content of the material. The wireless device can further include a first wireless transceiver communicably coupled to the moisture sensing circuitry for wirelessly communicating a second signal that represents the water content of the material. After receiving the first signal from the probe, the first wireless transceiver is activated to communicate the second signal.

The device can be configured to provide continuous or periodic indications of the moisture level of the material as well as to provide an instantaneous or current indication of the moisture level of the material. In addition to displaying an indication of the moisture content of material, the device can be configured to provide an indication that the moisture level in the material exceeds a specified threshold value or to provide an indication of the current moisture level.

In one embodiment, the wireless moisture monitoring device can include a remote receiver having a second wireless transceiver configured to receive the second signal the first wireless transceiver. That is, the remote receiver is configured to receive a wireless signal from the wireless moisture monitoring device that is inserted in the material. The remote receiver can further include one or more display devices configured to be actuated by receiving the signal from the wireless moisture monitoring device so as to provide a readout that represents the water or moisture content of the material.

While the moisture monitoring device disclosed herein is configured for wirelessly communicating data relating to moisture content of a material, the device can also include a switch on the device configured to actuate the moisture sensing circuitry and one or more display devices on the device so as to provide a readout thereon that is proportional to the magnitude of the first signal or that otherwise interprets the first signal to determine water or moisture content and that represents the water or moisture content of the material.

In one embodiment, the present invention can include a wireless moisture monitoring system. An exemplary wireless moisture monitoring system can include an irrigation control module communicatively coupled to one or more valves and one or more irrigation devices via one or communication lines, one or more wireless moisture monitoring devices for detecting moisture content in a material when each of the one or more devices is at least partially submerged in the material, and a moisture control module in communication with the irrigation control module and the one or more wireless moisture monitoring devices, the moisture control module including processing circuitry configured for receiving a wireless signal from the one or more wireless moisture monitoring devices and manipulating the signal for delivery to the irrigation control module to initiate activation and deactivation of the one or more irrigation devices based upon the detected moisture content.

In one embodiment, each of the one or more wireless moisture monitoring devices can include a probe that is inserted into the medium, moisture sensing circuitry being configured to produce a first signal that varies in magnitude with the moisture content detected by the probe that is inserted in the material or that contains information representative of the moisture content of the material, and a first wireless transceiver communicably coupled to the moisture sensing circuitry for processing the first signal and wirelessly communicating a second signal to the moisture control module, wherein the first and second signals each have a magnitude that is proportional to the moisture content of the material. In one embodiment, the magnitude of the signal can also vary according to the depth that the probe is inserted in the material.

In one embodiment, a method for providing for instantaneous measurement of moisture content in a material is disclosed. The method can include (1) providing one or more wireless moisture monitoring devices, each of the one or more wireless moisture monitoring devices including an elongate probe configured to be inserted into a material so as to the monitor the moisture content of the material, moisture sensing circuitry adapted for detecting water content when the probe is at least partially submerged in a material, and a first wireless transceiver for communicating a data stream that represents the water content of the material, (2) partially submerging the one or more probes in the material, (3) triggering at least one of the one or more wireless moisture monitoring devices using a second wireless transceiver in communication with the first wireless transceiver, wherein triggering the at least one of the one or more wireless moisture monitoring devices causes the moisture sensing circuitry to produce a signal that is proportional to the water content of the material, (4) converting and packaging the signal for wireless transmission to the second wireless transceiver, and (5) transmitting the signal to the second wireless transceiver from the first transceiver so as to provide an instantaneous indication of the moisture content of the material.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

To further clarify at least some of the advantages and features of the present invention, a more particular description of the invention will be rendered by reference to specific embodiments thereof which are illustrated in the appended drawings and exhibits, which are incorporated herein by this reference. It is appreciated that these drawings and exhibits depict only illustrated embodiments of the invention and are therefore not to be considered limiting of its scope. The invention will be described and explained with additional specificity and detail through the use of the accompanying drawings and exhibits in which:

FIG. 1A illustrates a perspective view of a moisture monitoring device according to one embodiment of the present invention;

FIG. 1B is an exploded perspective view of the moisture monitoring device of FIG. 1A;

FIG. 1C illustrates a rear perspective view of the moisture monitoring device of FIG. 1A;

FIG. 2A illustrates a perspective view of an embodiment of a transmission line probe where a flexible transmission line is mounted on a rigid support;

FIG. 2B illustrates a perspective view of an embodiment of a transmission line probe where a flexible transmission line is embedded in a circuit board;

FIGS. 3A-3B illustrate exemplary probes of the wireless moisture monitoring system of FIGS. 1A-1C in further detail.

FIG. 4 is a diagrammatic drawing of an exemplary wireless moisture monitoring system;

FIG. 5 illustrates a block diagram of an example of a moisture sensing circuit;

FIG. 6 illustrates one embodiment of a circuit diagram of a filter;

FIG. 7 illustrates one embodiment of a circuit diagram of a passive peak detector;

FIG. 8 illustrates a block diagram showing a multi-segment transmission line; and

FIG. 9 illustrates an embodiment of a moisture monitoring device according to the present invention incorporating a capacitive probe.

### DETAILED DESCRIPTION

Embodiments of the present invention are directed to a wireless moisture monitoring device that can be used measure the moisture content of a material (e.g., soil). Embodiments of the invention further relate to a wireless moisture monitoring system that can be used for wirelessly monitoring and controlling an irrigation system based upon moisture or water content of a material. By way of example only, the material may contain or support plants, shrubs, trees, grass, or the like. A method for wirelessly providing an instantaneous or current indication of the moisture content of a material is also presented.

A wireless moisture monitoring device may generally include a probe having moisture sensing circuitry adapted for detecting water content of a material when the probe is at least partially submerged in a material. One of skill in the art can appreciate that embodiments of the invention can detect liquid content and is not limited to water. The moisture sensing circuitry can be configured to produce a first signal that varies in magnitude with the water content of the material or that includes information conveying the water content of the material. The wireless device typically includes a first wireless transceiver communicably coupled to the moisture sensing circuitry for wirelessly communicating a second signal that represents the water content of the material, the first wireless transceiver being activated, by way of example, by receiving the first signal from the probe. Alternatively, the moisture content can be sampled over time and the first wireless transceiver can be activated on a scheduled basis.

In one embodiment, the wireless moisture monitoring device can include a remote receiver having a second wireless transceiver configured to receive the second signal the first wireless transceiver. That is, the remote receiver is configured to receive a wireless signal from the device whose probe is inserted in the material. In one embodiment, the remote receiver can further include one or more display devices configured to be actuated by receiving the signal from the device so as to provide a readout that represents the water content of the material.

Reference will now be made to the drawings to describe various aspects of exemplary embodiments of the invention. It should be understood that the drawings are diagrammatic and schematic representations of such exemplary embodiments and, accordingly, are not limiting of the scope of the present invention, nor are the drawings necessarily drawn to scale.

### I. A Moisture Monitoring Device

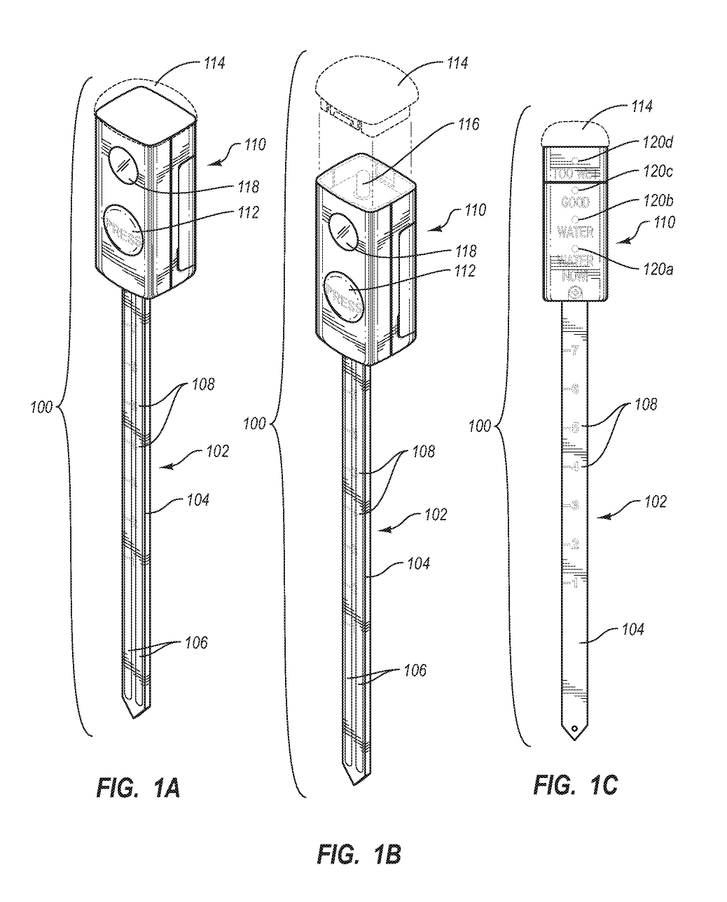

Referring now to FIGS. 1A-1C, various views of an exemplary wireless moisture monitoring device 100 are illustrated. In general, the more water or liquid a material contains, the higher its dielectric constant will be. The present invention uses a moisture monitoring device that can measure the dielectric constant of a material and use the measured dielectric constant to detect and quantify the moisture level in the material. Although embodiments of the invention are described in the context of water or moisture, one of skill in the art can appreciate, with the benefit of the present disclosure, that other level of content of other liquids or other materials could be quantified, in part by their impact on the dielectric constant.

In one embodiment, a moisture monitoring device 100 according to the present invention can include a probe 102 and a housing 110. In one embodiment, probe 102 can include a probe body 104 and a transmission line 106. For instance, probe body 104 can include a single or multiple layer electronic circuit printed circuit board with traces formed thereupon, which can function as a transmission line 106. In one embodiment, the probe can include printed depth indicia 108.

For instance, the probe 102 can include a standard circuit board assembly consisting of a number of circuit boards bonded together to form the rigid probe body 104. The transmission line 106 can be etched on one side of a first circuit board. A second pieced of printed circuit board material, similar in size and thickness to the first, can then be bonded to the first board so the transmission line is insulated from the medium in which it is placed. Additionally, an epoxy sealant can be applied to the rigid probe body 104 to further seal and protect the circuit components. While it is generally desirable to protect the probe circuitry from corrosion by sealing it from the medium, other configurations of the probe circuitry are possible. For instance, the transmission line 106 can be formed from an inexpensive, flexible wire material that is applied to the rigid probe body 104 to facilitate inserting the probe 102 into the medium.

Moisture monitoring device 100 can be configured to detect the moisture content of a material when probe 102 is inserted into the material. As will be discussed in greater detail in reference to the moisture sensing circuitry, the moisture monitoring device 100 can detect the moisture of the material by propagating a signal (e.g., a carrier wave) through transmission line 106 of the probe. The ability of device 100 to propagate the carrier wave or signal can be affected both by the water content of the material and by the depth that the probe 102 is inserted into the material. As such, the response of probe 102 can be calibrated for different soil types by selecting the length that the probe is inserted into the soil based on the soil type and/or the plant type. For instance, depth indicia 108 can allow a user to adapt the device 100 to different plant types and watering habits. For example, probe 102 can be inserted less deeply for wetter soil types (e.g., depth marks 1-3 for tropical plants), whereas drier soil types may require probe 102 to be inserted more deeply (e.g., depth marks 5-7 for desert plants), or in between (e.g., depth marks 3-5) for typical potting soils.

In one embodiment, the probe 104 of the moisture monitoring device 100 can further include a distal end having an active zone that includes at least a portion of the moisture sensing circuitry and inactive zone that is disposed proximally to the active zone (i.e., more toward the surface of the medium that the probe is inserted into). For example, the active zone can be approximately 3 inches in length and the inactive zone can be approximately 2 inches in length. Inserting the probe substantially vertically into the soil and placing the proximal end of the inactive zone at the soil surface helps to ensure that the active zone is in the relevant “root zone” for a variety of plants. This ensures that moisture measurements are occurring in the “root zone.” Inserting the probe 104 vertically into the soil also increases ease of use for the consumer and minimizes soil disturbance. This can provide a more accurate estimate of the moisture content in the region of the soil where plants typically need it most (i.e., the root zone). This can also encourage deep watering, which promotes water conservation, deep root growth, and increased plant vigor.

In one embodiment, the device 100 can be configured to provide a readout proportional to an average of the moisture content in the active zone. In conjunction with the depth of the active zone, this can provide increased accuracy in the estimate of the moisture content of the soil in the root zone. As was discussed in the previous paragraph, this can further encourage deep watering, which promotes water conservation, deep root growth, and increased plant vigor. Averaging the moisture reading over the active zone also provides for a degree of flexibility with respect to the depth that the probe 104 is inserted into the soil. That is, because the moisture reading is being averaged over a vertical depth range, the device 100 is less sensitive to the depth of insertion. Moreover, the user can easily adjust the device 100 to a particular watering situation by inserting the probe 104 more deeply into the soil (e.g., for a deeply rooted plant) or withdrawing the probe 104 slightly from the soil (e.g., for a plant having shallow roots).

In one embodiment, housing 110 can include a wireless transceiver configured for sending and receiving wireless signals. While the electronics can be contained in housing 110, a wireless transceiver is illustrated schematically at 118. The term “wireless transceiver” is used to refer to any hardware or software used to translate physically transmitted data into wirelessly transmitted data or vice versa. Because the term “wireless” can encompass any wireless transmission technique, the term “wireless transceiver” is similarly broadly construed as encompassing any hardware/software required to accomplish such translation. For example, a wireless signal including data relating to the moisture level of the material can be sent by the wireless transceiver in device 100 to a remote transceiver. In another example, a wireless signal including an “on/off' signal or an activation signal can be sent by a remote transceiver to wireless transceiver 118 to activate the device 100. The wireless signal can be sent via infrared, radio frequency, or another form of electromagnetic radiation known in the art for transmitting data wirelessly.

The signal output (e.g., the first signal and/or the second signal) from the transmission line 106 and the moisture sensing circuitry can be fed to a driver that drives wireless transceiver 118 to transmit a data stream that includes data relating to the moisture content of the material to a remote receiver. Any suitable driver may be used. In one embodiment, the driver may include logic for determining and interpreting the signal output from device 100 so that the remote receiver receives moisture data in order to display an appropriate indication of the moisture content of the material. The driver can also include software and/or hardware configured for interpreting and/or packaging data from the moisture sensing circuitry. In another embodiment, the driver may transmit the signal output from device 100 to a receiver having logic for determining and interpreting the signal output from device in order to display an appropriate indication of the moisture content of the material. The indication may be provided by displaying text, images, colors, or combinations of both on the remote receiver.

While device 100 is configured for wireless communication, it may also me desirable in some instances to be able to manually activate the device and observe the water content of the material. As such, in one embodiment, housing 110 can also include a button 112 for actuating the moisture monitoring device 100. Actuating the moisture monitoring device 100 can result in the display of moisture content at the device 100 itself and/or in the transmission of the moisture content via the transceiver 118.

FIG. 1B illustrates device 100 with having a cover 114 that is removed exposing an indicator 116, which can serve as a display device. Indicator 116 can be configured, for example, to indicate that device 100 is active or indicator 116 can be an LED, LCD, or another display device that is configured to indicate the moisture level of the material. In one embodiment, the display device (e.g., indicator 116) can be disposed within the housing 110 of the device 100 such that the light emitted by the display device exits through the top of the housing 110 and through a cap or removable cover 114.

The signal output (e.g., the first signal and/or the second signal) from the transmission line 106 and the moisture sensing circuitry can be fed to a driver that drives one or more of the display devices to display an indication of the moisture content of the material. In one embodiment, the driver may be an LED driver which drives a multicolor LED with a color hue that can be proportional to the signal, thus providing the indication of the moisture content of the measured material. Any suitable LED driver and LED may be used to provide the indication. For example, multicolor LEDs can be composed of several closely placed LEDs which each emit one primary color from the spectrum. Various color schemes can be used for displaying the relative moisture level of the soil. For example, red may be used to indicate excessive soil dryness, yellow to indicate water is needed, green to indicate ideal water content, and blue to indicate over-watering. The LED driver can be implemented in any suitable manner to provide the appropriate signal to drive the LEDs. For the purpose of conserving power, the LED driver can be implemented such that it only turns on the LEDs after a particular dryness threshold is reached. The LEDs may then be flashed at a periodic slow rate and at an appropriate color to indicate the moisture content of the soil. Such an approach can conserve the battery life of the moisture sensing device. Alternatively, one or more LEDs may remain on during use, with the particular color of the illuminated LED identifying the moisture content of the soil.

In another embodiment, the driver may be an LCD driver which drives an LCD to display the indication of the moisture content of the measured material. Any suitable LCD may be used. The LCD driver may include logic for determining an appropriate indication to display on the LCD based on the signal received from the circuitry. The indication may be provided by displaying text, images, colors, or combinations of both on the LCD.

In an alternative embodiment of the present invention shown in FIG. 1C, housing 110 can further include a series of water level indicators 120a-120d that can indicate the water content of the material and/or whether or not a plant needs water. For example, water level indicator 120a can include a colored light (e.g., a red LED) and corresponding text printed on the housing 110 indicating that the plant needs to be watered immediately; water level indicator 120b can include a second colored light (e.g., a yellow LED) and corresponding text printed on the housing 110 indicating that the plant needs water, but to a lesser extent that is indicated by water level indicator 120a; water level indicator 120c can include a third colored light (e.g., a green LED) and corresponding text printed on the housing 110 indicating that the plant does not need water (i.e., the water level in the soil is in a range acceptable for maintaining plant health and growth); and water level indicator 120c can include a fourth colored light (e.g., a blue LED) and corresponding text printed on the housing 110 indicating that the plant has been over watered.

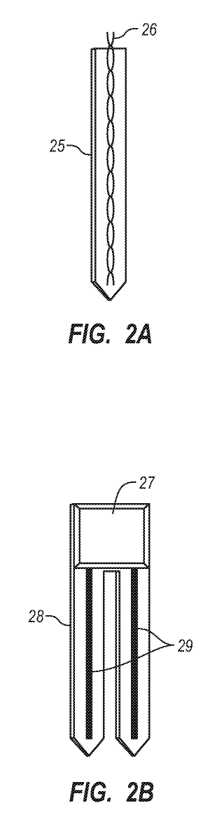

FIG. 2A shows another type of probe body that could be used. This probe can include an inexpensive flexible transmission line such as a twisted pair 26, and a rigid elongated brace or support 25, whereby the transmission line may be easily inserted into a bulk material.

FIG. 2B shows another type of probe body that can be used. It should be noted that this is just one example, and that many other circuit board shapes and geometries can be used. This probe can include a single or multiple layer electronic circuit printed circuit board 28 with traces 29 formed thereupon. These traces 29 function as transmission lines, on the circuit board 28. The sensor's electronic circuit can also be formed on the circuit board (not shown) and optionally encapsulated in a water tight covering 27.

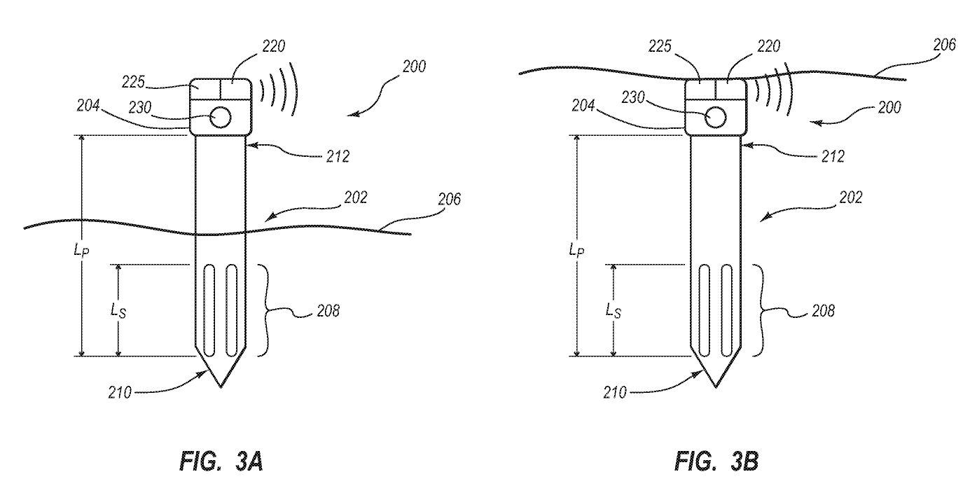

FIGS. 3A and 3B illustrate additional details of an exemplary wireless moisture monitoring device 200, wireless moisture monitoring device 200 can function similar to and replace the wireless moisture monitoring device 100 identified in FIG. 1A-1C. As such, the discussion of the wireless moisture monitoring devices 100 and 200 apply to each other.

As shown, the wireless moisture monitoring device 200 has an insertion member 202 (compare to probe 102 in FIGS. 1A-1C) and a housing 204. The insertion member 202, and optionally the housing 204, can be inserted into the soil 206 at least vertically or at an angle so that a portion of the insertion member 202 can extend from the level of the soil 206, as illustrated in FIG. 3A, or can be about or below the level of the soil 206, as illustrated in FIG. 3B. The configuration of the wireless moisture monitoring device 200 reduces inaccuracy in moisture monitoring because precise readings may be taken no matter the particular angle in which the insertion member 202 is inserted into the soil 206. The wireless moisture monitoring device 200 will provide an accurate moisture content reading provided that a sensing portion 208 of the insertion member 202 is surrounded by the material, such as soil 206, being tested for moisture content. Thus, the insertion member 202 may be inserted into the soil 206 at any angle to varying depth levels. This is beneficial because, unlike traditional moisture sensing systems which require a precise horizontal placement of the probe at a specific depth within the soil to achieve an accurate moisture level reading, the insertion member 202 of the present invention does not need to be placed horizontal and does not require professional installation to provide an accurate moisture level reading of the surrounding soil.

In one configuration, the sensing portion 208 has a length Lₛ of about 2-3 inches, while in another configuration the sensing portion 208 has a length Lₛ of about 1-4 inches. It will be understood that various lengths of sensing portion 208 may be applicable for testing the moisture level of the soil or other material into which the probe is placed. Further, the particular location of the sensing portion 208 upon the length of the probe Lₚ can be varied. For instance, the sensing portion 208 can be positioned nearer to a distal end 210 of the probe 200, positioned nearer a proximal end 212, or positioned at any location intermediate the proximal end 212 or distal end 210.

The signal output by the moisture sensing circuitry, which is described in detail below, can be fed to or provided to a wireless transceiver 220 for transmission to a remote receiver. Suitable examples of remote receivers can include a hand-held module configured to display soil moisture data transmitted from wireless moisture monitoring device 200 or the irrigation control module 120 and/or the moisture control module 325 or 325′ illustrated in FIG. 3. The wireless transceiver 220 communicates moisture level data in the form of a wireless signal to the irrigation control module 120 and/or moisture control module 325 or 325′.

The term “wireless transceiver” is used to refer to any hardware or software used to translate physically transmitted data into wirelessly transmitted data or vice versa. Because the term “wireless” can encompass any wireless transmission technique, the term “wireless transceiver” is similarly broadly construed as encompassing any hardware/software required to accomplish such translation. The hardware/software may be discretely contained within the probe 200, such as in the housing 204, the irrigation control module 320, the moisture control module 325 or 325′, or may be disposed on multiple different locations on a wireless device that operate together to form the function of a “wireless transceiver.” For example, components of a wireless transceiver may be located in various areas on one or more printed circuit boards and still be able to accomplish the task of converting physically transmitted data to wirelessly transmitted data or vice versa. Further, a “wireless transceiver” may be formed when coupling one unit containing some wireless transceiver components to a host device that contains other wireless transceiver components to cooperate together to operate as a wireless transceiver. In addition, the term “wireless transceiver” covers both the ability to transmit wirelessly transmitted data and/or to receive wirelessly transmitted data. In some embodiments, some wireless devices of the present invention will only be configured to transmit wirelessly transmitted data or configured to receive wirelessly transmitted data, both of which embodiments are contemplated within the scope of the term “wireless transceiver”. Thus, the term “wireless transceiver” is not dependent on the direction of the wireless transmissions being outgoing or incoming, but can include one or both directions.

The device 200 may be configured to provide continuous indications or periodic indications of the moisture level of the soil surrounding the device such as hourly, once a day, twice a day, prior to a moisture deliver event, such as a pre-arranged time to irrigate, etc, or any other time period that can be set internal to the device or optionally defined by the user or installer of an irrigation system. Further, the device 200 may be configured to provide a moisture level indication upon being queried, either manually by depressing button 230 or wirelessly from a remote receiver. As with device 100, device 200 can optionally include an LCD 225 or another display device for displaying the water content of the material.

### II. Wireless Moisture Monitoring System

In one embodiment, a wireless moisture monitoring system for monitoring soil moisture levels and controlling an irrigation system is described. In general, embodiments of a wireless moisture monitoring system are concerned with systems and methods for monitoring and controlling an irrigation system based upon moisture or water content of a material. Embodiments further relate to monitoring and controlling an irrigation system of a material containing or supporting plants, shrubs, trees, grass, or the like. For instance, the material may be soil, topsoil, potting soil, soilless growth media, peat, humus, compost, gravel, sand, cellulose material, or any other material within which it is desired to grow plants, shrubs, trees, grass, or the like. The moisture monitoring system described herein can be adapted for indoor and outdoor growing environments.

The system can include a moisture sensing device (e.g., a moisture sensing probe) that detects the moisture content of the material, such as soil in this exemplary configuration, and transmits moisture level data to a moisture control module. Based on the moisture level data received from the device, the moisture control module may activate or deactivate one or more irrigation devices to achieve the desired moisture content of the soil. The moisture sensing device may be configured to provide continuous or periodic indications of the moisture level of the soil surrounding the probe as well as to provide an instant indication of the moisture level on request.

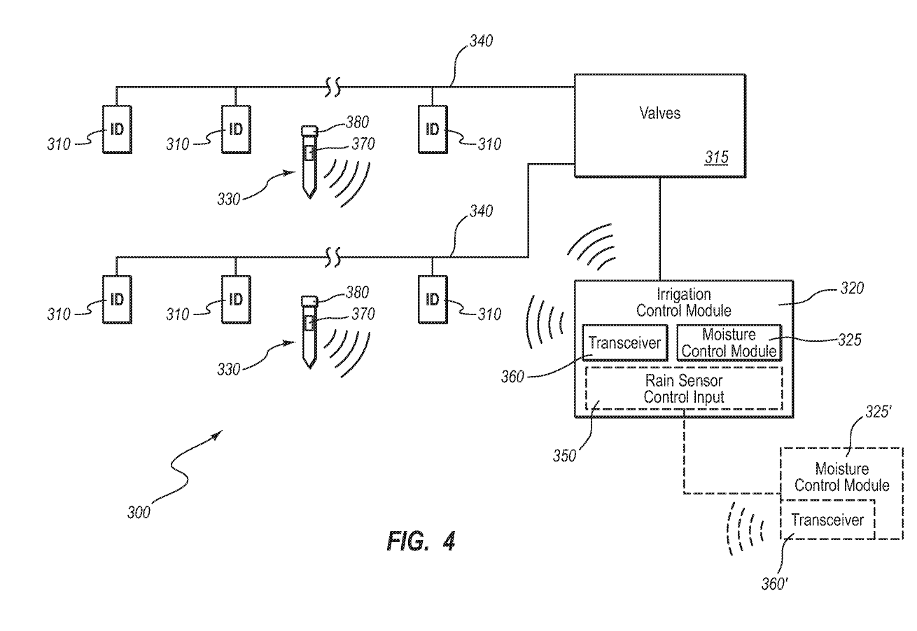

FIG. 4 illustrates an exemplary wireless moisture monitoring system 300 in which the principles of the present invention may be employed. As shown, the system may include a number of wireless moisture monitoring devices 330 for monitoring soil moisture and a number of irrigation devices 310 configured to deliver water, fertilizer, or the desired liquid to the material containing or supporting plants, shrubs, trees, grass, or the like, such as soil in this configuration. The irrigation devices 310 can include, but not limited to, sprinklers, drip lines, or other water delivery structures of an irrigation system. The number of moisture probes 330 and irrigation devices 310 shown are for illustrative purposes only and not as a limitation. The wireless moisture monitoring system 300 may be configured to control only one irrigation device or a complex network of several irrigation devices, such as sprinklers installed in various zones, drip lines installed in various zones, combinations thereof, or the like.

The wireless moisture monitoring devices 330 can be inserted in the soil, for example, in a location within the range of the irrigation devices 310. Wireless moisture monitoring device Wireless moisture monitoring device 330 can function similar to and replace probe 100 or 200 identified in FIG. 1A-2B. As such, the discussion of the wireless moisture monitoring devices 100, 200, and 330 apply to each other.

Each wireless moisture monitoring device wireless moisture monitoring device 330 can include circuitry for detecting the moisture level of the surrounding soil, such as, in one configuration, being based on the dielectric constant of the soil, which is described in further detail herein below. In one configuration, the wireless moisture monitoring devices 330 are located such that they provide moisture content indications that are representative of the majority area within the range of the irrigation devices 310. The number of wireless moisture monitoring devices 330 shown in FIG. 3 is for illustrative purposes only and not as limitation. Any number of wireless moisture monitoring devices may be implemented in the water monitoring system 300.

As illustrated in FIG. 3, the wireless moisture monitoring device 330 can each include a first wireless transceiver 170 for communicating data indicative of detected moisture level in the form of a wireless signal and optionally include an LED 180 configured to present a visual indication of the moisture content of the soil, for example.

The data indicative of detected moisture level can be delivered to the moisture control module 325 of an irrigation control module 320 via at least a second wireless transceiver 360. The moisture control module 325 can include software/hardware modules and circuitry for processing the signal received by wireless second transceiver 360 and can optionally include a rain sensor control input 350 to receive data from a wired or wireless rain sensor. The software/hardware modules and circuitry of the moisture control module 325 can manipulate or process the signal to identify the moisture content and determine whether additional moisture is needed. If moisture is needed, i.e., the moisture content is below a desired threshold level, the moisture control module 325 can signal the irrigation control module 320 to open the one or more valves 315 and allow the irrigation devices 310 to delivery liquid. Alternatively, if the moisture content is sufficient, i.e., moisture level is above a desired threshold level, the moisture control module 325 can signal the irrigation control module 320 to not irrigate. In this manner, the circuitry can manipulate the received signal to initiate activation and deactivation of the one or more irrigation devices 310 based upon the detected moisture content. In addition, wireless moisture monitoring devices 330 can each be assigned a unique identifying signal or another characteristic that can be used by the moisture control module 325, for example, to track and monitor the moisture content of the soil in individual areas of the irrigated zone. As such, the moisture control module 325 can be configured to deliver water only to those areas than need water.

The irrigation control module 320 is connected to one or more irrigation devices 310 via one or more valves 315 and one or more communication lines 340, such as pipes, conduits, etc. The irrigation control module 320 can include the moisture control module 325 and the second transceiver 360 for receiving the signal containing moisture level data from the wireless moisture monitoring device 330. As mentioned above, this received moisture level data drives the logic associated with software/hardware modules and circuitry of the moisture control module 325 and/or the irrigation control module 320 to initiate activation or deactivation of the one or more valves 315 to activate or deactivate the one or more irrigation devices 310 for a predetermined period of time or until a desired moisture level indication is received from the probe.

In another configuration, such as when the moisture monitoring system 300 includes a legacy or existing sprinkler delivery system with a legacy or existing sprinkler control system, the data from the wireless moisture monitoring device 330 is received by the transceiver 360 within a separate moisture control module 325′, which optionally receives power from a separate source, such as a battery or secondary source, or from the irrigation control module 320. This moisture control module 325′ can manipulate and analyze the received probe data using associated software/hardware modules and circuitry, and can then deliver data indicative of the moisture content to the input of a rain sensor control input or post 350 of the legacy or existing sprinkler delivery system. Alternatively, the moisture control module 325′ may deliver signals indicating how to control the valves 315 (e.g., turn one or more valves on/off). This results in the legacy or existing sprinkler delivery system operating and controlling the sprinklers or other irrigation device and enabling a homeowner or business to obtain the benefits of the monitoring system and method taught herein.

Stated another way, data from the probes 330 and the moisture control module 325′ can delivered to the legacy or existing sprinkler system through the rain sensor control input 350 instead of data or signals from a wired rain sensor. As such, the legacy or existing sprinkler system may be converted to the present system simply by replacing the wired moisture sensor input to the rain sensor control input 350 with an input received from a separate moisture control module 325′ that delivers an input to the rain sensor control input 350.

The wireless moisture monitoring device 330 may be configured to provide continuous indications or periodic indications of the moisture level of the soil surrounding the device such as hourly, once a day, twice a day, prior to a moisture deliver event, such as a pre-arrange time to irrigate, etc, or any other time period that can be set internal to the device or optionally defined by the user or installer of the system. In addition, the wireless moisture monitoring device 330 may be configured to provide a moisture level indication at a time just prior to commencement of normal irrigation operation, allowing the irrigation control module 320 to determine the necessary period of irrigation operation time to achieve the desired moisture level. Further, the wireless moisture monitoring device 330 may be configured to provide a moisture level indication upon being queried, either manually or wirelessly from the irrigation control module 320.

It will be understood, that in another configuration the moisture control module 125 or 125′ can initiate moisture level testing by querying the wireless moisture monitoring device 330. Consequently, the moisture control module 125 or 125′ can initiate testing on a continuous or periodic interval, including but not limited to, hourly, once a day, twice a day, prior to a moisture deliver event, such as a pre-arrange time to irrigate, etc, or any other time period that can be set internal to the moisture control module 125 or 125′ or optionally defined by the user or installer of the system.

In one embodiment, the wireless moisture monitoring device 330 is configured to periodically monitor the moisture level or other moisture characteristic in the surrounding soil and to periodically transmit a moisture level indication to the moisture control module 125 or 125′. Transmitting the moisture level indication to the moisture control module 125 or 125′ may consume a relatively large amount of power compared to the power needed to monitor the moisture level, for example, in the surrounding soil. Thus, the moisture monitoring device 330 may be configured to conserve power by periodically monitoring the moisture level in the surrounding soil on a first schedule and periodically transmitting the moisture level indication to the moisture control module 125 or 125′ on a second schedule that may be less frequent.

For example, the wireless moisture monitoring device 330 may be configured to monitor the moisture level of the surrounding soil with a delay between monitoring events. Such delay can be from about 1 hour to about 12 hours, about 2 hours to about 10 hours, about 3 hours to about 8 hours, about 4 hours to about 6 hours, or from about 4 hours between soil moisture monitoring events. While the wireless moisture monitoring device 330 may be configured to monitor the moisture level of the surrounding soil with a delay between monitoring events of, for example, about 4 hours, the soil moisture level may be transmitted to the moisture control module 125 or 125′ less frequently. For example, the soil moisture level may be transmitted to the moisture control module 125 or 125′ twice per day (i.e., about every 12 hours), once per day, once every 36 hours, once every 48 hours, once every 72 hours, or anytime therebetween. However, if the moisture level of the surrounding soil changes by an amount greater than a pre-determined threshold amount between moisture monitoring events, the moisture monitoring device 330 may be configured to transmit the moisture level indication to the moisture control module 125 or 125′ earlier than the scheduled interval. For example, if the soil moisture level changes (i.e., increases or decreases) by an amount of about 2% to about 20%, about 3% to about 18%, about 5% to about 15%, or about 10% the moisture monitoring device 330 may be configured to transmit the moisture level indication to the moisture control module 125 or 125′ earlier than the scheduled interval. The wireless moisture monitoring device 330 may further be configured to send a moisture level indication to the moisture control module 125 or 125′ when the moisture content of the surrounding soil exceeds a predetermined threshold or drops below a predetermined threshold, thereby avoiding overwatering or underwatering. Thus, ensuring that the soil maintains minimum moisture content at all times.

It will be understood, that varying monitoring delays and transmission times are possible, with such delays and transmission times being selectable by the manufacturer of the system, components or parts of the system, or the user of the system. Further, although hourly increments are provided herein, it will be understood that smaller increments of time are also possible, such as but not limited to, half-hour, quarter-hour, tenths of an hour, or any other desired increments of time. It will also be understood that the lengths of the time may be greater than those examples provided herein.

Similarly, although soil moisture level changes (i.e., increases or decreases) are illustrated, it will be understood by one skilled in the art that soil moister level changes greater and lesser than those exemplary configurations are possible. Consequently, soil moisture levels less than about 2% to greater than about 20% are possible.

### III. Moisture Sensing Circuitry

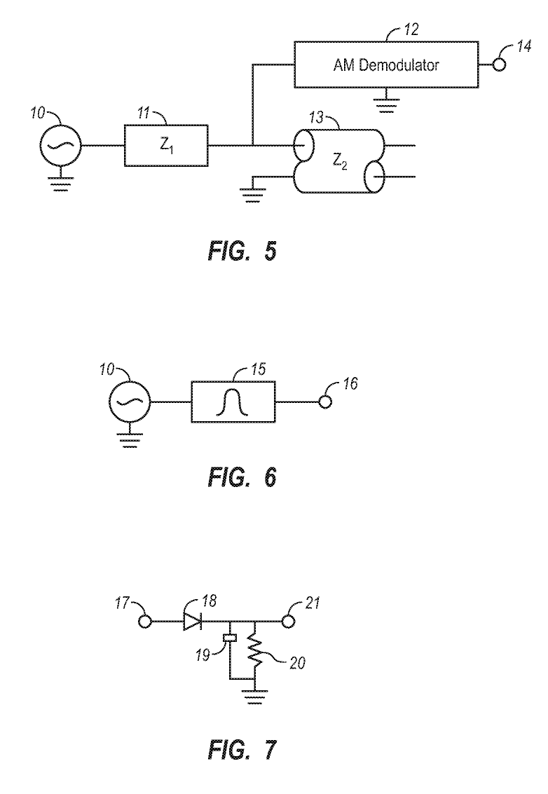

Referring now to FIGS. 5-9, moisture sensing circuitry is illustrated. The moisture sensing circuitry described herein can be composed entirely of passive components such as diodes, resistors, and capacitors. As such, the moisture sensing circuitry does not require a separate power supply to power active components and the power consumption can be very low, which can lengthen battery life.

The dielectric constant of materials such as soils varies with water content and most materials having a higher water or liquid content will have a higher dielectric constant. The moisture monitoring device illustrated herein uses moisture sensing circuitry to measure the dielectric constant of a material and produce a signal therefrom that varies according to the magnitude of the dielectric constant. That is, the more water a material contains, the higher its dielectric constant will be and the stronger the signal will be. The moisture sensing circuitry can thus be configured to measure the dielectric constant of a material and use the measured dielectric constant to detect and quantify the moisture level in the material.

The moisture monitoring device described herein uses moisture sensing circuitry that can create a carrier wave or signal whose magnitude varies depending on the dielectric constant of the surrounding material. In general, the moisture sensing circuitry does not interact directly with the medium (i.e., the circuitry does not directly contact the medium). Instead, the circuitry is designed to propagate a signal through the circuit, the magnitude of which is a function of the dielectric constant of the medium. That is, the magnitude of the carrier wave varies with the dielectric constant of the medium because the dielectric constant of the medium alters the ability to propagate a signal through the circuit, which in turn alters the resistance of the circuit. A higher dielectric constant provides for a stronger carrier stronger signal, which is interpreted by the circuitry in the device as indicating a higher moisture content in the medium.

Several examples of moisture sensing circuitry are shown schematically in FIGS. 5-9. For example, as shown in FIG. 5, a periodic function generator 10 may provide the carrier frequency that is coupled to a transmission line probe 13 through a resistive or reactive element 11. The resistive or reactive element and the transmission line form a simple voltage divider whose output voltage is related to the impedance of the transmission line, which is in turn related to the dielectric constant of the medium and the magnitude of the carrier wave.

A voltage divider is a linear circuit that produces an output voltage (Vₒᵤₜ) that is a fraction of its input voltage (Vᵢₙ). Applying Ohm's Law (Formula 1), the relationship between the input voltage, Vᵢₙ, and the output voltage, Vₒᵤₜ, can be found:

$${V}_{out} = \frac{{Z}_{2}}{{Z}_{1} + {Z}_{2 }} \cdot {V}_{i n} \qquad Formula 1$$

A voltage divider is created by connecting two electrical impedances in series (e.g., Z₁ at 11 and Z₂ at 13 in FIG. 5). The input voltage is applied across the series impedances Z₁ and Z₂ and the output is the voltage across Z₂. Z₁ and Z₂ may be composed of any combination of elements such as resistors, inductors and capacitors.

The electrical impedance of transmission line 13 and the magnitude of the resulting carrier frequency (i.e., the carrier wave) varies according to the dielectric constant of the transmission line probe and correspondingly with the moisture of the material surrounding the transmission line. Because the dielectric constant of the material surrounding transmission line 13 affects the electrical impedance of transmission line 13, it can be appreciated that for a given input voltage provided by a power source (e.g., a 1.5 volt battery), the output voltage that is detected at 14 will vary in proportion to the dielectric constant of the of the material that transmission line 13 is inserted in. The voltage detected at 14 is thus representative of the moisture content of the material that transmission line 13 is inserted in.

In the example shown in FIG. 5, the output of this voltage divider is fed to an Amplitude Modulated (AM) demodulator 12 to remove the carrier, rendering a voltage to the sensor output 14, which is related to the to the moisture of the material surrounding the transmission line probe 13.

The signal generator 10 may produce any periodic carrier frequency to stimulate the transmission line 13. Many data electronic recording systems already have numerous oscillators or clock sources which can be used for this purpose. For instance, the circuitry described herein can be stimulated by any periodic signal including, but not limited to, sine, square, and triangular waves. If a non-square periodic signal is available in the systems, this signal can be used to stimulate the transmission line without the extra cost associated with adding a square-wave oscillator. These periodic waves can be band pass filtered or low pass filtered if the desired frequency is the fundamental frequency of the waveform, to produce a single frequency carrier. Thus, in the embodiment of FIG. 6, a filter circuit 15 is used to produce a single carrier frequency.

Turning to the reactance of the device, the reactance of transmission lines alternates between negative and positive values every quarter wavelength of the carrier frequency in one embodiment, as the transmission line length increases. For example, a transmission line with an open circuit load has a negative reactance when the length of the line is less than a quarter wavelength of the carrier, and positive from above a quarter wavelength to below one half a wave length, and so on. The even quarter wavelength nodes are resonance points. Thus, in practice the carrier and the length of the transmission line can be chosen for a desired reactance point. For example, the length of an open load transmission line could be chosen to be less than one quarter of a wavelength such that the reactance is negative. For applications where it is desired that the length of the transmission line be minimized, a higher carrier frequency could be used. As a result, the selection of the carrier frequency can impact how the probe is inserted into the material.

The resistive or reactive element 11 can be composed of a single resistor, but other reactive elements such as inductors or capacitors, or combinations thereof, can be used.

Many types of AM demodulators can be used, from specialized integrated circuits, to simple passive demodulators. One such passive demodulator is illustrated in FIG. 7. This is also known as a peak detector, and can include an input 17, a rectifier 18, a parallel connected capacitor 19, and resistor 20. The peak detector removes the carrier frequency and renders a waveform on the output 21, which tracks the envelope of the modulating frequency. Because passive components can be used, in one configuration, no separate power supply is needed to power the electronic circuit, and the voltage supply only need be slightly greater than the forward voltage of the rectifying diode, allowing the circuit to use a very low voltage carrier. This circuit consumes very little power, making it ideal for remote battery operated applications. It will be understood, that in other configurations active components may be used.

The output of the sensor can be digitized using various methods, including the use of an analog to digital converter (ADC). This digitized signal can be passed to a microcontroller or computer system for further processing, such as averaging to remove noise and determination of the moisture content. The relationship between the voltage from the demodulator and the water moisture can be derived from a lookup table in the microcontroller that contains known relationship values for voltage and moisture content. It may alternatively be determined by the computer system by computing the reactance of the transmission line element given the known values of the carrier amplitude, and the impedance of the reactive or resistive element 11. Once the reactance of the probe is known the dielectric constant and correspondingly the water content of the bulk material may then be identified. In one example, the look up table can be calibrated for the transmission line of the device. This may also help ensure that readings received from multiple devices are standardized and have a similar or same meaning.

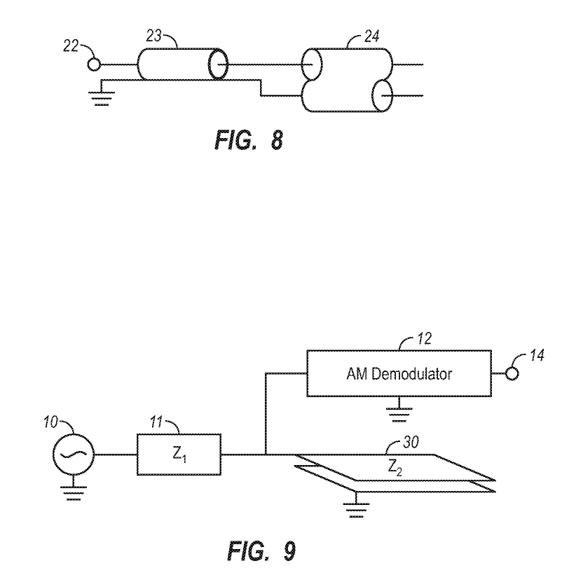

Many types of transmission line based probes can be used for the device. FIG. 8 shows a multi-segmented transmission line, wherein a transmission line that is insensitive to the dielectric constant of the medium or material through which it passes 23, such as coax, is used to couple the carrier frequency to the second transmission line which is sensitive to the carrier frequency 24. This is useful in applications where the sensor probe needs to be placed remotely away from the sensor electronics.

A block diagram of another alternative embodiment is illustrated in FIG. 9. A periodic function generator 10 provides a carrier frequency that is coupled to a capacitive probe 30 through a resistive or reactive element 11. The resistive or reactive element 11 with the transmission line forms a simple voltage divider, whose output voltage is related to the impedance of the capacitor. The magnitude of the carrier frequency can vary according to the dielectric constant of the material in which the probe is inserted. The output of this voltage divider can be fed to an AM demodulator 12 for the purpose of removing the carrier, and rendering a voltage to the sensor output 14 which is related to the moisture of the material surrounding the transmission line probe.

As with the other embodiments discussed herein, this embodiment may similarly make use of a peak detector for the AM demodulator, and a filter circuit for the carrier signal.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A wireless device for measuring moisture content, comprising:
a probe having moisture sensing circuitry adapted for detecting moisture content when the probe is submerged in a material, the circuitry being configured to produce a first signal that varies in magnitude with the moisture content of the material; and
a first wireless transceiver communicably coupled to the moisture sensing circuitry for wirelessly communicating a second signal that represents the moisture content of the material, the first wireless transceiver being activated by receiving the first signal from the probe.

2. The device of claim 1, the probe further including:
a distal end including an active zone that includes at least a portion of the moisture sensing circuitry, the active zone being configured for detecting moisture content of the material; and
an inactive zone disposed proximal to the active zone,
wherein the active zone and at least a portion of the inactive zone are inserted substantially vertically into the material.

3. The device of claim 3, wherein the device is configured to provide a readout proportional to an average of the moisture content in the active zone.

4. The device of claim 1, the material being at least one of soil, topsoil, potting soil, soil less growth media, peat, humus, compost, gravel, sand, or cellulose material.

5. The device of claim 1, the moisture sensing circuitry further comprising, an electrical circuit that includes:
a power source configured to provide a source voltage;
a periodic function generator configured to provide a carrier wave;
a transmission line having at a first segment and a second segment, the first and second segments being electrically coupled;
the first segment including a first resistive or reactive element configured to provide a substantially constant electrical impedance;
the second segment including a second resistive or reactive element configured to provide an electrical impedance that varies with the water content of the material; and
an electronic filter means that is electrically coupled to the power source, the periodic function generator, and the first and second segments, the electronic filter means configured to filter out the carrier wave and provide a voltage signal that is a fraction of the source voltage.

6. The device of claim 5, the voltage signal being proportional to the moisture content of the material.

7. The device of claim 1 further comprising, a receiver having a second wireless transceiver configured to receive the second signal the first wireless transceiver.

8. The device of claim 7, the receiver further comprising one or more display devices configured to be actuatable by receiving the second signal from the first wireless transceiver and to provide a readout therefrom that represents the water content of the material.

9. The device of claim 8, the one or more display devices including at least one of one or more Light Emitting Diodes (LEDs) or one or more Liquid Crystal Displays (LCDs).

10. The device of claim 9, the one or more LEDs including at least one LED having a color that represents the water content of the material.

11. The device of claim 9, further comprising at least one LED that is configured to be illuminated when the water content of the material exceeds a specified threshold value indicating that the material contains excess water.

12. The device of claim 7, the second wireless transceiver being configured to transmit a third signal to the first transceiver so as to actuate the moisture sensing circuitry.

13. The device of claim 12, wherein the probe is in an inactive state until the third signal is received by the first transceiver.

14. The device of claim 1 further comprising, a switch on the probe configured to actuate the moisture sensing circuitry and one or more display devices on the probe so as to provide a readout thereon that is proportional to the magnitude of the first signal and that represents the water content of the material.

15. A wireless moisture monitoring system comprising:
an irrigation control module communicatively coupled to one or more valves and one or more irrigation devices via one or communication lines;
one or more wireless moisture monitoring devices for detecting moisture content in a material capable of supporting plant growth when each of the one or more wireless moisture monitoring devices is at least partially submerged in the material, each of the one or more wireless moisture monitoring devices comprising:
an elongate probe including:
a distal end including an active zone configured for detecting moisture content of the material; and
an inactive zone disposed proximal to the active zone,
wherein the active zone and at least a portion of the inactive zone are inserted substantially vertically into the material;
moisture sensing circuitry configured to create a signal that varies with the moisture content in the material; and
a first wireless transceiver communicably coupled to the moisture sensing circuitry for communicating the signal; and
a moisture control module in communication with the irrigation control module and configured to initiate activation and deactivation of the one or more irrigation devices, the moisture control module comprising circuitry for processing a wireless signal received by the moisture control module from the one or more probes, the circuitry manipulating the signal for delivery to the irrigation control module to initiate activation and deactivation of the one or more irrigation devices based upon the detected moisture content.

16. The system of claim 15, wherein each of the one or more probes is configured to provide a first signal proportional to an average of the moisture content in the active zone.

17. The system of claim 15, wherein one or more of the probes, the moisture sensing circuitry, the first transceiver, and/or the moisture control module is configured to activate the one or more irrigation devices so as to apply a selected amount of water to the medium based on a specified threshold value.

18. The system of claim 15, wherein one or more of the probes, the moisture sensing circuitry, the first transceiver, and/or the moisture control module is configured to deactivate the one or more irrigation devices based on a specified signal magnitude when the medium reaches a selected moisture level.

19. The system of claim 18, further comprising delay circuitry that delays deactivation of the one or more irrigation devices for a selected period of time when the medium reaches the selected moisture level.

20. The system of claim 15, the transceiver further comprising:
filtering circuitry being adapted to receive the first signal from the moisture sensing circuitry, generate the second signal therefrom, and deliver the second signal to the transceiver,
the second signal having a magnitude that is proportional to the magnitude of the first signal.

21. A method for providing for instantaneous measurement of moisture content, the method comprising:
providing one or more wireless moisture monitoring devices, each of the one or more wireless moisture monitoring devices including an elongate probe configured to be inserted into a material so as to the monitor the moisture content of the material, moisture sensing circuitry adapted for detecting water content when the probe is at least partially submerged in a material, and a first wireless transceiver for communicating a data stream that represents the water content of the material;
partially submerging the one or more probes in the material;
triggering at least one of the one or more wireless moisture monitoring devices using a second wireless transceiver in communication with the first wireless transceiver, wherein triggering the at least one of the one or more wireless moisture monitoring devices causes the moisture sensing circuitry to produce a signal that is proportional to the water content of the material;
converting and packaging the signal for wireless transmission to the second wireless transceiver; and
transmitting the signal to the second wireless transceiver from the first transceiver so as to provide an instantaneous indication of the moisture content of the material.

22. The method of claim 21, the receiver further comprising one or more display devices configured to be actuatable by receiving the second signal from the first wireless transceiver and to provide a readout therefrom that represents the water content of the material.

23. The method of claim 21, wherein the one or more display devices remain illuminated for a defined duration of time after the button is pressed.

24. The method of claim 21, the one or more display devices including at least one of one or more Light Emitting Diodes (LEDs) or one or more Liquid Crystal Displays (LCDs).

25. The method of claim 24, the one or more LEDs including at least one LED having a color that represents the water content of the material.

26. The method of claim 24, further comprising at least one LED that is configured to be illuminated when the water content of the material exceeds a specified threshold value indicating that the material contains excess water.
